(19) United States
(12) Patent Application Publication
(10) Pub. No.: US 2025/0237674 A1
(43) Pub. Date: Jul. 24, 2025

(54) SIGNAL TRSANSMISSION CONNECTOR

(71) Applicant: TSE CO., LTD., Chungcheongnam-do (KR)

(72) Inventors: Bo Hyun Kim, Chungcheongnam-do (KR); Yun Chan Nam, Chungcheongnam-do (KR); Dae Hyun Roh, Chungcheongnam-do (KR)

(21) Appl. No.: 19/021,414

(22) Filed: Jan. 15, 2025

(30) Foreign Application Priority Data
Jan. 20, 2024 (KR) 10-2024-0009150

(51) Int. Cl. G01R 1/04

(52) U.S. Cl. CPC G01R 1/0416

(57) ABSTRACT

The signal transmission connector according to the present disclosure has a configuration in which a plurality of electro-conductive members having elasticity are arranged in the support member, an upper housing and a lower housing made of an inelastic material are placed on upper and lower surfaces of the support member, respectively, and an inner wall constituting a housing hole formed in each of the upper and lower housings is spaced apart from and surrounds the electro-conductive member, whereby the electro-conductive member can be replaced and it is possible to easily cope with the device under test having a large warpage.

### CROSS-REFERENCE TO RELATED APPLICATION

This application claims priority of Korean Patent Application No. 10-2024-0009150, filed on Jan. 20, 2024, in the KIPO (Korean Intellectual Property Office), the disclosure of which is incorporated herein entirely by reference.

### BACKGROUND OF THE INVENTION

### Field of the Invention

The present disclosure relates to a signal transmission connector, and more specifically, to a signal transmission connector connected to an electronic component such a semiconductor device to transmit an electrical signal, and a method for manufacturing the same.

### Description of the Related Art

Currently, various types of connectors for transmitting electrical signals have been used in various fields such as electronic and semiconductor industries.

In the case of semiconductor devices, they are manufactured through a front-end-of-line (FEOL), a back-end-of-line (BEOL), and a test process, and among these processes, the test process is a process for testing whether the semiconductor device is being normally operated to select normal products and defective products.

One of the key components applied to the test process is a signal transmission connector called a so-called test socket. The test socket is mounted on a printed circuit board electrically connected to an integrated circuit tester and is used to inspect semiconductor devices. The test socket is equipped with a contact pin, and this contact pin electrically connects a terminal (lead) of the semiconductor device and a terminal of the printed circuit board. The tester generates an electrical signal for testing the semiconductor device to be connected to the test socket, outputs it to the semiconductor device, and then uses the electrical signal input through the semiconductor device to test whether the semiconductor device is normally operated normally. Based on the test result, the semiconductor device is determined to be good or defective.

Typically, a pogo socket and a rubber socket have been used as the test socket.

The pogo socket is made by assembling pogo pins, which are individually manufactured, into a housing. Recently, the demand for rubber sockets has been increased in the semiconductor device test process due to problems such as damage to a package ball and an increased unit price.

The rubber socket has a configuration in which electro-conductive parts, each of which having a plurality of electro-conductive particles contained in an elastic material such as silicon, are insulated from each other and disposed at an inside of an insulating part made of an elastic material such as silicone. Such rubber socket has the characteristic of exhibiting conductivity only in a thickness direction, and has the advantage of excellent durability and achieving simple electrical connection since no mechanical means such as soldering or springs are used therein. In addition, since this rubber socket can absorb mechanical shock or deformation, this has the advantage of being capable of being smoothly connected to semiconductor device, etc.

Since the conventional signal transmission connector consisting of the rubber socket has a configuration in which the electro-conductive parts are structurally connected to each other through an insulating part, a pressurizing force (or stroke) applied to one electro-conductive part has also influence on another adjacent electro-conductive parts through the insulating part. Therefore, if there is a tolerance in the height of the semiconductor package terminal or there is warpage in the semiconductor package, there is a problem that there are difference in the degree of compression applied to the electro-conductive parts, so the electro-conductive part subject to concentrated stress is broken or a contact failure in which the terminal does not come into contact with the electro-conductive part may occur.

Accordingly, recently, a rubber socket in which an electro-conductive part is operated independently has been developed. As shown in FIGS. 1 and 2, a signal transmission connector 20 consisting of a rubber socket having electro-conductive parts, which are operated independently, includes a housing 21 made of an inelastic material; a plurality of electro-conductive parts 25, each of which having an electro-conductive part body 23 made of an elastic insulating material containing a plurality of electro-conductive particles therein and an electro-conductive part lower bump 24; and an upper insulating sheet 28 and a lower insulating sheet 26 attached on upper and lower surfaces of the housing, respectively, such that each electro-conductive part body 23 is spaced apart from an inner wall constituting each of housing holes 22 of the housing 21, wherein each electro-conductive part 25 has a configuration in which the electro-conductive part body 23 is connected to the electro-conductive part lower bump 24 through a lower sheet hole 27 of the lower insulating sheet 26.

In the above signal transmission connector, when a pressurizing means (not shown) pressurizes a device 10 under test for testing the device under test, a terminal 11 of the device under test comes into contact with an upper end of the electro-conductive part body 23 through an upper sheet hole 29 of the upper insulating sheet 28 to pressurize the electro-conductive part body. At this time, the adjacent electro-conductive part bodies 23 are structurally separated from each other, so they are compressed independently, and an intermediate portion of each electro-conductive body 23 expands to a space between the electro-conductive body 23 and the inner wall of the housing hole 22. When the electro-conductive part body 23 is compressed, a compressive force thereof is also transmitted to the electro-conductive part lower bump 24, so the electro-conductive part body 23 and the electro-conductive part lower bump 24 are in electrical communication with each other and are electrically connected to a pad 31 of a tester 31. Consequently, the tester 30 is electrically connected to the device 10 under test through the signal transmission connector 20 to perform a test for the device under test.

As described above, the plurality of electro-conductive parts of the conventional signal transmission connector are operated independently. Therefore, when there is a slight tolerance in the height of terminals of a semiconductor package or the semiconductor package is lightly warped, this signal transmission connector can cope with these problems to a certain extent.

Since the conventional signal transmission connector is manufactured to have configuration in which the electro-conductive part lower bump 24 and the electro-conductive part body 23 having a larger diameter than that of the lower sheet 27 are integrally connected in the lower sheet hole 27 of the lower insulating sheet 26, there is a problem in that even if any one of the electro-conductive parts is damaged, the entire signal transmission connector should be replaced with new one.

In the conventional signal transmission connector, in addition, since a thickness of the electro-conductive part lower bump coming into contact with the pad of the tester is limited to a certain thickness range causing inducing fine movement while not reducing durability, so in order to increase a thickness of the signal transmission connector, a thickness of one side of the electro-conductive part body excluding electro-conductive part lower bump should be increased. However, the electro-conductive part body having a large aspect ratio has low durability, and it is difficult to align the electro-conductive particles in the elastic insulating material in a thickness direction, so the electro-conductive part has high resistance characteristics, which causes problems in that the reliability of the product is deteriorated.

Furthermore, since the conventional signal transmission connector provided with the electro-conductive parts having the same thickness functions as a hard stop that limits a pressurization of the housing formed of an inelastic material when the device under test is pressurized for testing, The device under test, which is significantly warped, has the problem that the degree of compression of the electro-conductive parts varies from one electro-conductive part to another, so the electro-conductive part subject to concentrated stress is broken or a contact failure in which the terminal does not come into contact with the electro-conductive part may occur.

### SUMMARY OF THE INVENTION

The present disclosure is conceived in view of the above-described problems, and an object of the present disclosure is to provide a signal transmission connector capable of replacing an electro-conductive member and easily coping with to a device under test which is significantly warped.

In order to achieve the above-mentioned object, the present disclosure provides a signal transmission connector connecting terminals of a device under test to pads of a tester, which generates a test signal, to perform an electrical test for the device under test, the signal transmission connector may include a plurality of electro-conductive members, each of which being formed of an elastic insulating material in which a plurality of electro-conductive particles are arranged in a thickness direction, and having a truncated conical upper bump being able to come into contact with the terminal of the device under test, an inversed truncated conical lower bump being able to come into contact with the pad of the test, and a cylindrical connecting bump extending between the upper bump and the lower bump; an insulating support member having an upper surface and an opposite lower surface, and provided with a plurality of support holes formed therein, each of the support holes being coupled with the corresponding connecting bump; an upper housing formed of an inelastic material, attached to the upper surface of the support member, and having a plurality of upper housing holes, an inner wall constituting each upper housing hole being spaced apart from and surrounding the corresponding upper bump; and a lower housing formed of an inelastic material, attached to the lower surface of the support member, and having a plurality of lower housing holes, an inner wall constituting each lower housing hole being spaced apart from and surrounding the corresponding lower bump, wherein a width of the connecting bump is not smaller than those of a lower surface of the upper bump and an upper surface of the lower bump, and a thickness of the lower bump is not smaller than that of the lower housing.

A thickness of the upper bump of at least one of the plurality of electro-conductive members may differ from a thickness of the upper bump of another electro-conductive member.

A thickness of the upper bump may be not less than a thickness of the upper housing.

A thickness of the upper bump may be less than a thickness of the upper housing.

The upper housing and the lower housing may be formed to have the same thickness.

The upper housing and the lower housing may be formed to have thicknesses different from each other.

Each of the plurality of electro-conductive members may be attached and coupled to an inner wall constituting the support hole of the support member by curing the elastic insulating material.

At least one of a plurality of electro-conductive members may be attached and coupled to the support hole of the support member by curing a silicone adhesive applied to a side surface of the connecting bump.

The upper housing and the lower housing may be made of an insulating material.

The upper housing and the lower housing may be made of an electro-conductive material, an insulating layer may be formed on an inner wall of each of the upper housing hole and the lower housing hole.

In the signal transmission connector according to the present disclosure, when only some of the plurality of electro-conductive members is defective or damaged, only the defective or damaged electro-conductive member may be individually replaced with new one without replacing the entire signal transmission connector, so that the manufacturing time of the signal transmission connector can be shortened and the manufacturing and maintenance costs of the signal transmission connector can be significantly reduced.

Also, in the signal transmission connector according to the present disclosure, by placing the electro-conductive members provided with the upper bumps having different thicknesses depending on the degree of warpage of the device under test, it is possible to transmit a constant stroke to each of the electro-conductive members. Therefore, damage to the electro-conductive members due to concentrated stress applied to the electro-conductive members and contact failure due to the stroke which is not inaccurately transmitted to the electro-conductive members can be prevented, as a result, the durability of the signal transmission connector can be improved, and stable signal transmission can be achieved, thereby improving the efficiency of the test.

In addition, in the signal transmission connector according to the present disclosure, since the electro-conductive members are disposed in the upper housing and the lower housing made of an inelastic material while spaced apart from each other, the electro-conductive members can be compressed or expanded independently and freely, thereby minimizing the influence caused by the adjacent electro-conductive members during a test and minimizing the influence caused by electrical shorts or leakage currents generated by a contact between the electro-conductive members.

Furthermore, in the signal transmission connector according to the present disclosure, the upper housing and the lower housing are configured such that the inner walls constituting the upper housing hole and the lower housing hole are spaced apart from and surround the electro-conductive members, and the space formed by the gaps between the upper housing and the electro-conductive member and between the lower housing and the electro-conductive member is filled with the air layer having a relative permittivity of 1, thereby lowering the overall permittivity and thus minimizing signal interference between the electro-conductive materials. As a result, the signal transmission connector according to the present disclosure can also be useful for high-speed signal transmission.

Also, in the signal transmission connector according to the present disclosure, since a separate space in which the electro-conductive member can expand is provided, the pressure applied to the electro-conductive member can be dispersed, so damage to the electro-conductive member can be prevented, thereby extending the life of the signal transmission connector.

In addition, in the signal transmission connector according to the present disclosure, since the electro-conductive member is formed such that the upper bump and the lower bump are connected to upper and lower sides of the connecting bump, respectively, when it is necessary to increase a thickness of the signal transmission connector, this can be achieved by increasing the thicknesses of both the upper and lower bumps of the electro-conductive member, thus significantly reducing the possibility of durability problem or high resistance problem occurring.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a conventional signal transmission connector;

FIG. 2 illustrates a test process using a conventional signal transmission connector;

FIG. 3 illustrates a signal transmission connector according to one embodiment of the present disclosure;

FIG. 4 is a partial perspective view of a signal transmission connector according to one embodiment of the present disclosure;

FIG. 5 illustrates a modified example of a signal transmission connector according to one embodiment of the present disclosure;

FIG. 6 illustrates a test process using a signal transmission connector according to one embodiment of the present disclosure;

FIGS. 7 and 8 illustrate a process for manufacturing a signal transmission connector according to one embodiment of the present disclosure;

FIG. 9 illustrates an upper bump mold for varying a thickness of an upper bump of an electro-conductive member;

FIG. 10 illustrates a process for replacing a damaged electro-conductive member with new one in a signal transmission connector according to one embodiment of the present disclosure; and.

FIG. 11 illustrates a state in which a signal transmission connector according to one embodiment of the present disclosure is connected to a device under test having a large warpage.

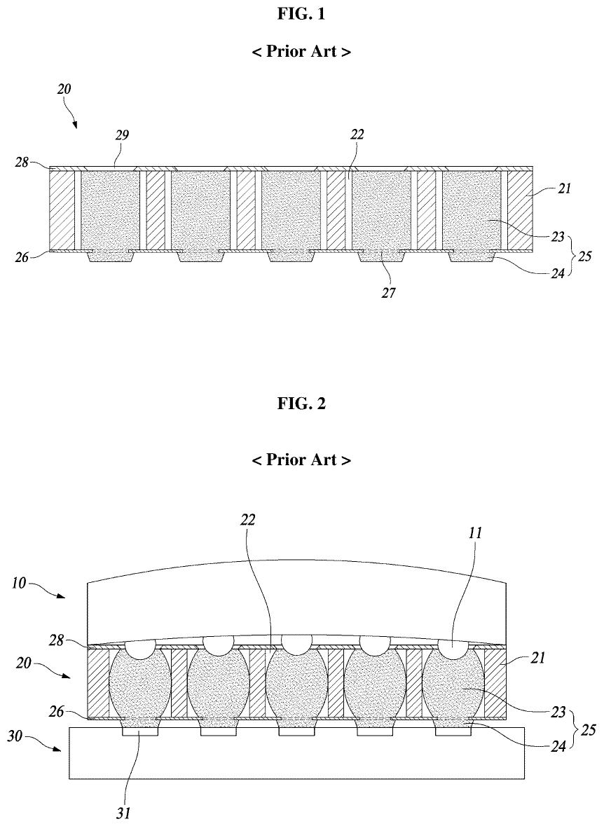

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a modular test socket according to the present disclosure will be described in detail with reference to the accompanying drawings.

In the present disclosure, a device under test is placed on an upper side of a test socket, and a tester is placed on a lower side of the test socket, so “upper surface”, “upper side”, “upper end”, and “lower surface”, “lower side”, “lower end” of any component will be described based on this configuration. In addition, the same components as those components previously described are indicated by the same reference numerals, and a description thereof is omitted.

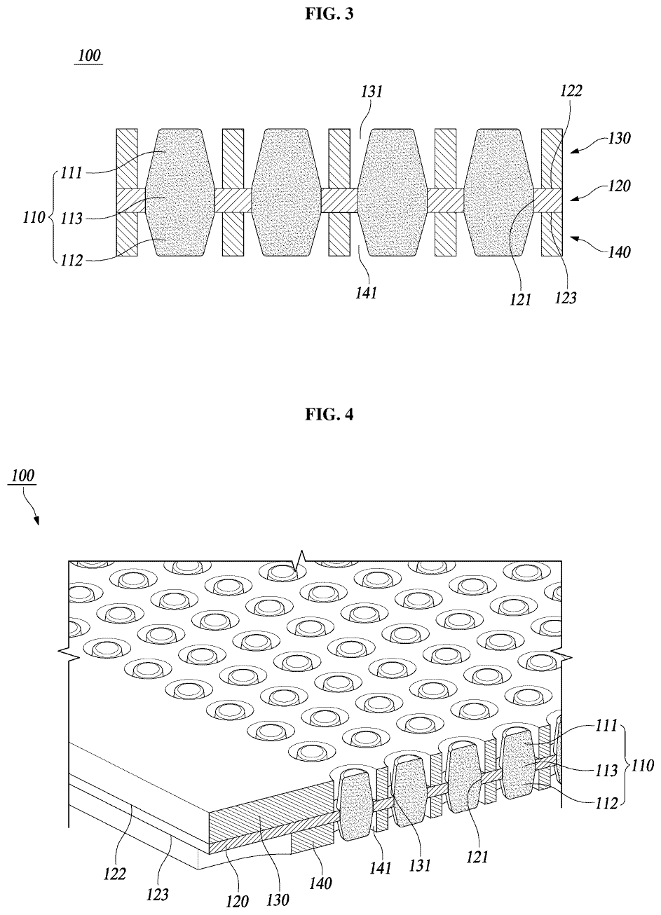

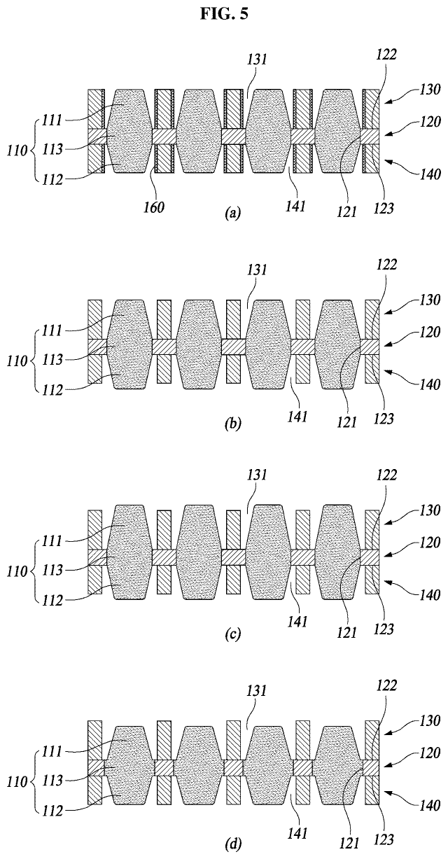

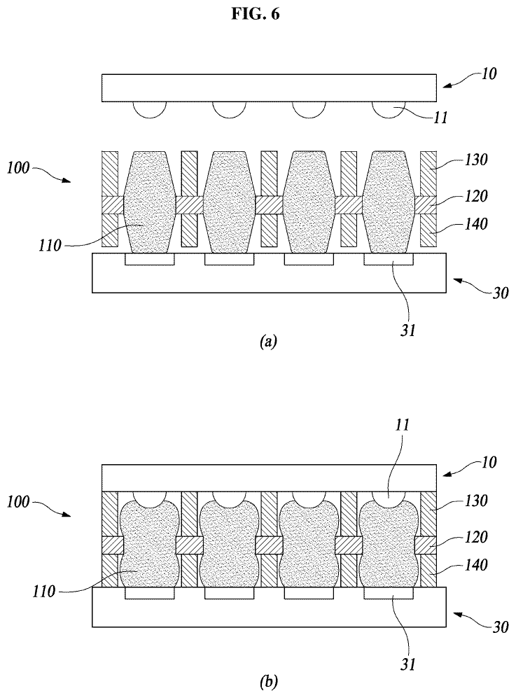

FIG. 3 illustrates a signal transmission connector according to one embodiment of the present disclosure, FIG. 4 is a partial perspective view of a signal transmission connector according to one embodiment of the present disclosure, FIG. 5 illustrates a modified example of a signal transmission connector according to one embodiment of the present disclosure, and FIG. 6 illustrates a test process using a signal transmission connector according to one embodiment of the present disclosure.

As shown in the drawings, a signal transmission connector 100 according to one embodiment of the present disclosure is a connector which connects terminals 11 of a device 10 under test to pads 31 of a tester 30, which generates a test signal, to perform an electrical test for the device under test, and this signal transmission connector may include a plurality of electro-conductive members 110, each of which being formed of an elastic insulating material in which a plurality of electro-conductive particles are arranged in a thickness direction, and having a truncated conical upper bump 111 being able to come into contact with the terminal of the device under test, an inversed truncated conical lower bump 112 being able to come into contact with the pad of the test, and a cylindrical connecting bump 113 extending between the upper bump and the lower bump; an insulating support member 120 having an upper surface 122 and an opposite lower surface 123, and provided with a plurality of support holes 121 formed therein, each of the support holes being coupled with the corresponding connecting bump; an upper housing 130 formed of an inelastic material, attached to the upper surface of the support member, and having a plurality of upper housing holes 131, an inner wall constituting each upper housing hole being spaced apart from and surrounding the corresponding upper bump; and a lower housing 140 formed of an inelastic material, attached to the lower surface of the support member, and having a plurality of lower housing holes 141, an inner wall constituting each lower housing hole being spaced apart from and surrounding the corresponding lower bump. Here, this signal transmission connector is characterized in that a width of the connecting bump is not smaller than those of a lower surface of the upper bump and an upper surface of the lower bump, and a thickness of the lower bump is not smaller than that of the lower housing.

In such signal transmission connector 100, the upper bump 111 of the electro-conductive member 10 comes into contact with the terminal of the device under test placed above the upper housing 130 and the lower bump 112 of the electro-conductive member comes into contact with the pad of the tester placed below the lower housing 140 to transmit an electrical signal from the tester to the device under test. Therefore, the signal transmission connector enables the device under test to be tested through a tester, or can electrically connect the device under test to various electronic devices to transmit the electrical signal. Hereinafter, providing the signal transmission connector 100 according to one embodiment of the present disclosure in the tester 30 to perform a function of transmitting the electrical signal between the tester 30 and the device 10 under test is described as an example.

In the signal transmission connector 100 according to one embodiment of the present disclosure, in order to allow an upper end of each electro-conductive member to be connected to the terminal 11 of the device 10 under test and a lower end to be connected to the pad 31 of the tester 30, each electro-conductive member 110 may be formed in a form in which a plurality of electro-conductive particles are arranged in the thickness direction (i.e., upward and downward direction) of the electro-conductive member within an elastic insulating material. Therefore, the electro-conductive member has elasticity and can elastically come into contact with the terminal 11 of the device under test and the pad 31 of the tester. The plurality of electro-conductive members 110 are formed at positions corresponding to the terminals 11, respectively, which are provided on the device 10 under test and will be connected to the electro-conductive members.

Each of the electro-conductive members 110 may include the upper bump 111 being capable of coming into contact with the terminal 11 of the device under test, the lower bump 112 being capable of coming into contact with the pad 31 of the tester, and the connecting bump 113 extending between the upper bump 111 and the lower bump 112.

The upper bump 111 of the electro-conductive member 110 may be formed in a truncated conical shape, the lower bump 112 may be formed in an inversed truncated conical shape, and the connecting bump 113 may be from in a cylindrical shape having the same with as a width of the lower surface of the upper bump and the upper surface of the lower bump. However, as exemplarily shown in (d) of FIG. 5, it is also possible to form the connecting bump 113 such that its width is larger than the width of the lower surface of the upper bump and the upper surface of the lower bump. If the width of the connecting bump 113 is large, it is easy to align the electro-conductive member 110 with the support hole 121 of the support member 120 when replacing it individually with new one, so it can be attached and combined at a more accurate position. In this way, the electro-conductive member 110 has a shape in which the connecting bump 113 has the largest width.

As an elastic insulating material constituting the electro-conductive member 110, a heat-resistant polymer material having a crosslinked structure, for example, silicone rubber, polybutadiene rubber, natural rubber, polyisoprene rubber, styrene-butadiene copolymer rubber, acrylonitrile-butadiene copolymer rubber, styrene-butadiene-diene block copolymer rubber, styrene-isoprene block copolymer rubber, urethane rubber, polyester rubber, epichlorohydrin rubber, ethylene-propylene copolymer rubber, ethylene-propylene-Diene copolymer rubber, soft liquid epoxy rubber, and the like may be employed.

In addition, as the electro-conductive particle constituting the electro-conductive member 110, the particles having magnetism may be employed so that they can be reacted by a magnetic field. For example, as the electro-conductive particles, particles obtained by plating a surface of core particle, for example, particles of metals exhibiting magnetism, such as iron, nickel, cobalt, etc., or alloy particles thereof, or particles containing these metals, or particles of these metals, with a metal having excellent electrical-conductivity, such as gold, silver, palladium, radium, or the like; particles obtained by plating a surface of core particle, for example, non-magnetic metal particles, inorganic substance particles such as glass beads or the like, and polymer particles, with electro-conductive magnetic substance such as nickel, cobalt, or the like; or particles obtained by plating core particle with electro-conductive magnetic substance and a metal having excellent electrical-conductivity may be employed.

The support member 120 has the lower surface 123 opposing the upper surface 122, and is provided with the support holes 121 at positions, which correspond to the electro-conductive members 110, respectively. By coupling the connecting bump 113 to the support hole 121 of the member 120, the member can support the plurality of electro-conductive members 110.

The support member 120 is made of an insulating material, and although it is preferable to use a polyimide sheet as the insulating material, it is also possible to use another insulator if it can support the electro-conductive member. The method of connecting the connecting bump 113 of the electro-conductive member to the support hole 121 of the support member will be described later.

The upper housing is attached to the upper surface 122 of the support member (120), and the lower housing 140 is attached to the lower surface 123 of the support member 120. The upper housing 130 and the lower housing 140 may be attached to the support member 120 with an adhesive, but are not limited thereto, and may also be fastened using screws or the like.

The upper housing 130 and the lower housing 140 constitute a body of the signal transmission connector 100, and are provided with the upper housing holes 131 and the lower housing holes 141, respectively, having a diameter larger than the diameter of the electro-conductive member 110. In addition, the upper housing holes and the lower housing holes are formed at positions corresponding to the electro-conductive members 130, respectively.

The upper housing 130 and the lower housing 140 may be made of an inelastic insulating material or an inelastic electro-conductive material. As the inelastic insulating material, engineering plastics such as polyimide, or various other inelastic insulating materials may be used, and electro-conductive metal such as aluminum, copper, brass, SUS, iron, nickel, and the like, or various materials that have both conductivity and inelastic property may be employed as the inelastic electro-conductive material. The upper housing 130 and the lower housing 140 made of such an inelastic material have a hardness which is sufficient to prevent a compressive deformation from being caused by a maximum pressurizing force applied through the device 10 under test during a test process, and have a characteristic of not being easily elastically deformed unlike an elastic insulating part of a conventional rubber socket.

If the upper housing 130 and the lower housing 140 are made of an electro-conductive material, it is preferable to form an insulating layer 160 on inner walls of the upper housing hole 131 and the lower housing hole 141, as shown in (a) of FIG. 5. This is to prevent electrical shorts from occurring due to direct contact between the electro-conductive member and the upper housing or the lower housing made of an electro-conductive material. Such insulating layer 160 may be formed not only on the inner walls of the upper housing hole 131 and the lower housing hole 141, but also on an upper surface of the upper housing 130 and a lower surface of the lower housing 140, thereby preventing the terminal 11 of the device under test or the pad 31 of the tester from coming into contact with the upper housing or the lower housing made of the electro-conductive material.

The upper housing 130 is disposed on the upper surface 122 of the support member such that the inner wall of each upper housing hole 131 is spaced apart from and surrounds the corresponding upper bump 111 of the electro-conductive member, and the lower housing 140 is disposed on the lower surface 123 of the support member such that the inner wall of each lower housing hole 141 is spaced apart from and surrounds the corresponding lower bump 112 of the electro-conductive member.

Therefore, a space formed by gaps between the upper housing 130 and the upper bump 111 and between the lower housing 140 and the lower bump 112 may be filled with an air layer having a relative permittivity of 1, and the space formed by the above gaps may also be used as a space that accommodates expansion portions of the upper bump 111 and the lower bump 112 of the electro-conductive member when the upper bump 111 and the lower bump 112 of the electro-conductive member are compressed by the terminal 11 of the device under test.

The upper housing 130 may have a thickness that is not greater than that of the upper bump 111 or may have a thickness that is greater than that of the upper bump 111. In addition, it is preferable that the lower housing 140 have a thickness that is not greater than that of the lower bump 112 so that it is possible to achieve a stable connection between the lower bump and the pad 31 of the tester. FIGS. 3 and 4 illustrate a configuration in which a thickness of the upper bump 111 of the electro-conductive member is the same as that of the upper housing and a thickness of the lower bump 112 of the electro-conductive member is the same as that of the lower housing, (b) of FIG. 5 illustrates a configuration in which a thickness of the upper bump 111 of the electro-conductive member is the same as that of the upper housing and a thickness of the lower bump 112 of the electro-conductive member is greater than that of the lower housing, and (c) of FIG. 5 (c) illustrates a configuration in which a thickness of the upper bump 111 of the electro-conductive member is greater than that of the upper housing and a thickness of the lower bump 112 of the electro-conductive member is greater than that of the lower housing,

As shown in the above drawings, the electro-conductive member is formed such that a thickness of the upper bump 111 is not smaller than a thickness of the upper housing 130. That is, a thickness of the upper bump 111 of the electro-conductive member may be equal to or larger than the thickness of the upper housing 130. A configuration, in which a thickness of the upper bump 111 is greater than that of the upper housing 130 and the upper bump is thus protruded, is useful in cases where the device under test is an LGA (land grid array) terminal because the upper bump can be more easily connected to a flat shaped LGA terminal.

Also, as shown in (d) of FIG. 5, the electro-conductive member may also be formed to allow a thickness of the upper bump 111 to be smaller than a thickness of the upper housing 130. In the configuration in which the upper housing 130 protrudes from the upper bump 111 of the electro-conductive member, a protruding portion of the upper housing 130 can serve as a ball guide to guide the terminal 11 in the form of a BGA (ball grid array), of the device under test toward the upper bump 111 of the electro-conductive member, so this configuration may be usefully applied in a case where an alignment between the terminal 11 of the device under test and the electro-conductive member 110 is particularly necessary.

The electro-conductive member is formed such that a thickness of the lower bump 112 is not smaller than a thickness of the lower housing 140. That is, a thickness of the lower bump 112 of the electro-conductive member may be equal to or greater than a thickness of the lower housing 140. It is more preferable for a thickness of the lower bump 112 of the electro-conductive member to be greater than a thickness of the lower housing 140, so as to enable the lower bump to be firmly connected to the pad 31 of the tester.

In addition, the upper housing 130 and the lower housing 140 may be formed to have the different thickness or have the same thickness. The degree to which the lower bump 112 of the electro-conductive member protrudes downward from the lower housing 140 may also be adjusted by using a thickness of the lower housing 140, and a thickness of the lower housing 140 may be thus different from a thickness of the upper housing 130. In addition, the upper housing 130 and the lower housing 140 may be formed to have the same thickness and the upper housing hole 131 and the lower housing hole 141 may be formed to have the same width, so the upper housing 130 and the lower housing 140 have the same shape. By using the upper housing and the lower housing having the same shape, it is possible to reduce a manufacturing cost for the signal transmission connector.

FIG. 6 illustrates a test process using the signal transmission connector 100 according to one embodiment of the present disclosure.

As shown in the drawing, when a pressurizing means (not shown) pressurizes the device 10 under test for testing the device 10 under test, the terminals 11 of the device under test compress the electro-conductive members 110 of the signal transmission connector 100 mounted on the tester 30, and the test is performed.

When the upper bump 111 of each electro-conductive member is compressed by the pressurization of the terminal 11 of the device under test, the upper bump 111 expands in the space formed within the gap between the upper housing hole and the electro-conductive member, and a compressive force is transmitted to the lower bump 112 of the electro-conductive member through the connecting bump 113, so the upper bump 111, the connecting bump 113, and the lower bump 112 of the electro-conductive member are in electric communication with each other. In addition, since the adjacent electro-conductive members 110 are structurally separated from each other by the upper housing and the lower housing, the electro-conductive members may be compressed independently without affecting each other. As each of the electro-conductive members 110 is compressed, the signal transmission connector 100 becomes electrical communication with the device 10 under test and the tester 30, so a test signal of the tester 30 is transmitted to the device 10 under test through the signal transmission connector to perform a test for the device under test.

Therefore, in the signal transmission connector according to one embodiment of the present disclosure, since the electro-conductive members are disposed in the upper housing and the lower housing made of an inelastic material while spaced apart from each other, the electro-conductive members can be compressed or expanded independently and freely, thereby minimizing the influence caused by the adjacent electro-conductive members during a test and minimizing the influence caused by electrical shorts or leakage currents generated by a contact between the electro-conductive members.

In addition, in the signal transmission connector according to one embodiment of the present disclosure, the upper housing 130 and the lower housing 140 are configured such that the inner walls constituting the upper housing hole 131 and the lower housing hole 141 are spaced apart from and surround the electro-conductive members 110, and the space formed by the gaps between the upper housing and the electro-conductive member and between the lower housing and the electro-conductive member is filled with the air layer having a relative permittivity of 1, thereby lowering the overall permittivity and thus minimizing signal interference between the electro-conductive materials. As a result, the signal transmission connector according to one embodiment of the present disclosure can also be useful for high-speed signal transmission.

In addition, in the signal transmission connector according to one embodiment of the present disclosure, since a separate space in which the electro-conductive member can expand is provided, the pressure applied to the electro-conductive member can be dispersed, so damage to the electro-conductive member can be prevented, thereby extending the life of the signal transmission connector.

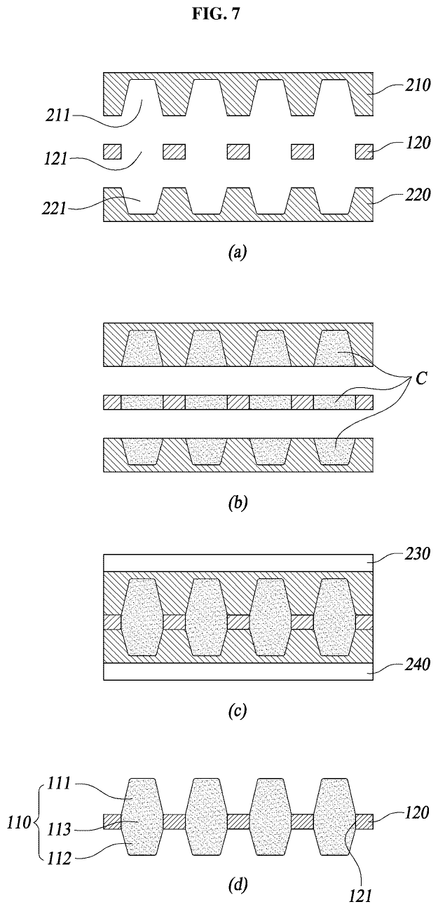

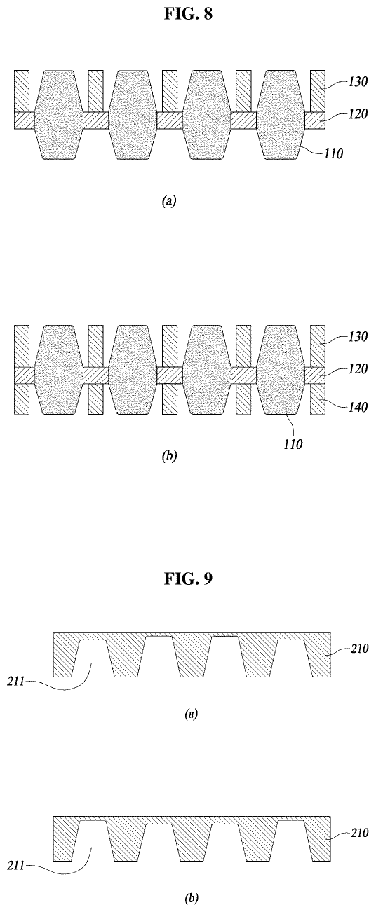

Referring to FIGS. 7 and 8, a method for manufacturing the signal transmission connector 100 according to one embodiment of the present disclosure is described.

FIG. 7 illustrates a process in which the plurality of electro-conductive members 110 are coupled to the support member 120. First, as shown in (a) of FIG. 7, an upper bump mold 210 having upper mold recesses 211 having a shape corresponding to the upper bump of the electro-conductive member, a lower bump mold 220 having lower mold recesses 221 having a shape corresponding to the lower bump of the electro-conductive member, and the support member 120 having the support holes 121 are prepared. At this time, each upper mold recess 211, each lower mold recess 221, and each support hole 121 are formed at a position corresponding to the terminal of the device under test.

Next, as shown in (b) of FIG. 7, the upper mold recesses 211 of the upper bump mold, the lower mold recesses 221 of the lower bump mold, and the support holes 121 of the support member are filled with an electro-conductive particle mixture C consisting of an elastic insulating material in which a plurality of electro-conductive particles are contained.

Next, as shown in (c) of FIG. 7, the upper bump mold 210, the support member 120, and the lower bump mold 220 filled with the electro-conductive particle mixture are combined to each other, and are then placed between an upper magnetic-force mold 230 and a lower magnetic-force mold 240. Each of the upper magnetic-force mold 230 and the lower magnetic-force mold 240 is provided with magnetic poles (not shown) placed at positions corresponding to the upper mold recesses 211, the lower mold recesses221, and the support holes 121, respectively. When a magnetic field is applied in a vertical direction to the electro-conductive particle mixture C through the magnetic poles, the electro-conductive particles dispersed within the elastic insulating material are oriented in the vertical direction under the influence of the magnetic field to form an electrical path. A curing process is then performed. The curing process may be performed between the upper magnetic-force mold 230 and the lower magnetic-force mold 240 as shown. As the method for curing the electro-conductive particle mixture C, various methods may be used depending on the characteristics of the electro-conductive particle mixture C, such as a method of heating the electro-conductive particle mixture to a certain temperature and then cooling it to a room temperature, or the like. The elastic insulating material is cured in the curing process, and is then attached and bonded to an inner wall constituting each support hole 121 of the support member to form the connecting bump 113.

Next, as shown in (d) of FIG. 7, when the upper bump mold 210 and the lower bump mold 220 after removing the upper magnetic-force mold and the lower magnetic-force mold 240, a process for manufacturing a structure in which the electro-conductive members 110 are combined with the support member 120 is completed. That is, the connecting bumps 113 of the electro-conductive members 110 are fixed in the support holes 121 of the support member 120, respectively, and the upper bump 111 and the lower bump 112 are formed integrally with upper and lower surfaces of each connecting bump, respectively.

FIG. 8 shows a process of coupling the upper housing and the lower housing to the support member. As shown in (a) of FIG. 8, the upper housing 130 having the upper housing holes 131, each of which having an outer diameter greater than that of the upper bump and formed at a position corresponding to the upper bump 111 of the electro-conductive member, is attached to the upper surface of the support member 120. At this time, the upper housing 130 is attached to the upper surface of the support member 120 such that the inner wall constituting each upper housing hole 131 is spaced apart from and surrounds each upper bump 111 of the electro-conductive member.

Next, as shown in (b) of FIG. 8, the lower housing 140 having the lower housing holes 141, each of which having an outer diameter greater than that of the lower bump and formed at a position corresponding to the lower bump 112 of the electro-conductive member, is attached to the lower surface of the support member 120. At this time, the lower housing 140 is attached to the lower surface of the support member 120 such that the inner wall constituting each lower housing hole 141 is spaced apart from and surrounds each lower bump 112 of the electro-conductive member. Through this method, the manufacturing of the signal transmission connector 100 according to one embodiment of the present disclosure is completed.

Therefore, in the signal transmission connector according to one embodiment of the present disclosure, since the electro-conductive member is formed such that the upper bump and the lower bump are connected to upper and lower sides of the connecting bump, respectively, when it is necessary to increase a thickness of the signal transmission connector, this can be achieved by increasing the thicknesses of both the upper and lower bumps of the electro-conductive member, thus significantly reducing the possibility of durability problem or high resistance problem occurring.

In addition, it is also possible to separately manufacture only the electro-conductive member 110 constituting the signal transmission connector. For example, by using a support mold having the same shape as that of the support member 120 in place of the support member 120 shown in (a) of FIG. 7, and even by removing the support mold in the step d of FIG. 7, a plurality of electro-conductive members which are not attached to the support member may be separately manufactured.

Furthermore, it is also possible to manufacture the signal transmission connector having the upper bumps 111, which have the thicknesses different from each other, of the electro-conductive member. As shown in FIG. 9, by manufacturing the upper bump mold 210 having the plurality of upper mold recesses 211 such that a thickness (that is, a depth) of some of the upper mold recesses 211 differs from that of other mold recesses, it is possible to form the upper bumps having thicknesses different from each other. For example, (a) of FIG. 9 shows the upper bump mold configured such that two upper mold recesses formed in a central region have a depth greater than that of periphery upper mold recesses, thereby obtaining the electro-conductive member in which the upper bumps disposed in the central region are thicker than the periphery upper bumpers. In addition, (b) of FIG. 9 shows the upper bump mold configured such that two upper mold recesses formed in the central region have a depth smaller than that of periphery upper mold recesses, thereby obtaining the electro-conductive member in which a thickness of the upper bumps disposed in the central region is smaller than that of the periphery upper bumpers. By performing the processes of FIGS. 7 and 8 using such the upper bump mold, it is possible to manufacture the signal transmission connector having the upper bumps with different thicknesses.

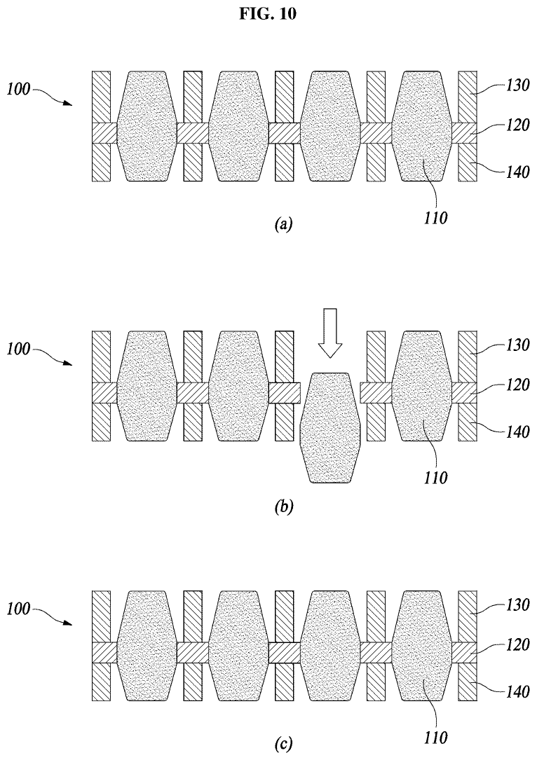

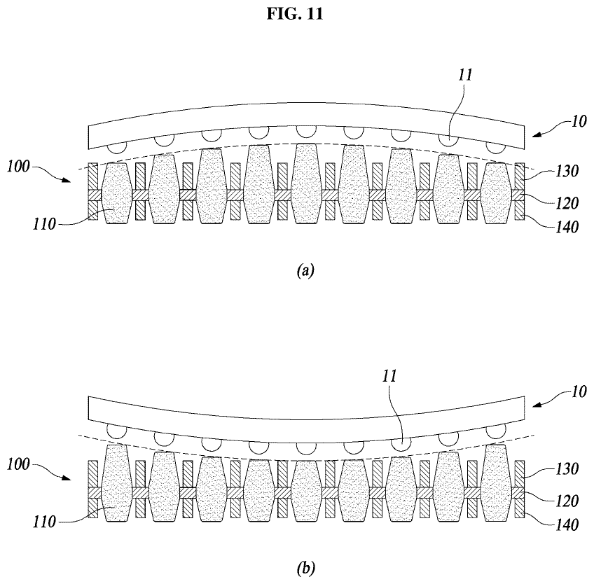

FIG. 10 illustrates a process for individually replacing the defective or damaged electro-conductive members when a characteristic of one or more electro-conductive members is defective in a process of manufacturing the signal transmission connector, or when one or more electro-conductive members are damaged during a repetitive test process.

(a) of FIG. 10 exemplarily illustrates a case where the second electro-conductive member 110 from the right in the signal transmission connector is defective or damaged.

As shown in (b) of FIG. 10, when a downward pressure is applied to the defective or damaged electro-conductive member, the electro-conductive member 110 can be removed from the support hole 121 of the support member 120. That is, since the electro-conductive member 110 has a shape in which the connecting bump has the largest width, the shape of the electro-conductive member does not interfere with its removal when the electro-conductive member is removed from the support hole of the support member. In addition, since a side surface of the connecting bump is attached to the inner wall constituting the support hole of the support member during a curing process of the elastic insulating material, an adhesion between the connecting bump and the support member is not large, and therefore, it is possible to remove the defective or damaged electro-conductive member from the support hole of the support member by applying a certain pressure.

Next, as shown in (c) of FIG. 10, the electro-conductive member which has been separately manufactured may be inserted and attached to the support member. That is, a silicone adhesive is applied to a side surface of the connecting bump of the electro-conductive member which has been separately manufactured, the connecting bump to which the silicone adhesive is applied is placed into the support hole of the support member, and the silicone adhesive is then cured through a curing process, so the connecting bump of the electro-conductive member is attached and coupled to the inner wall constituting the support hole of the support member. Through this process, the defective or damaged electro-conductive member can be easily replaced individually with new one.

Therefore, in the signal transmission connector according to one embodiment of the present disclosure, when only some of the plurality of electro-conductive members is defective or damaged, only the defective or damaged electro-conductive member may be individually replaced with new one without replacing the entire signal transmission connector, so that the manufacturing time of the signal transmission connector can be shortened and the manufacturing and maintenance costs of the signal transmission connector can be significantly reduced.

The signal transmission connector according to one embodiment of the present disclosure may be easily applied to a device under test which is significantly warped.

(a) of FIG. 11 exemplarily shows the signal transmission connector having the upper bumps with different thicknesses to enable it to be stably connected to the device under test whose peripheral portion is warped downward relative to the central portion. As shown in the drawing, by using the signal transmission connector 100 having the electro-conductive members 110 in which the upper bumps, which have thicknesses corresponding to height of the terminals of the device under test whose peripheral portion is warped downward relative to the central portion, are disposed, the terminals 11 of the device 10 under test and the electro-conductive members 110 may come into simultaneously contact with other to perform a test.

(b) of FIG. 11 exemplarily shows the signal transmission connector having the upper bumps with different thicknesses to enable it to be stably connected to the device under test whose peripheral portion is warped upward relative to the central portion. As shown in the drawing, by using the signal transmission connector 100 having the electro-conductive members 110 in which the upper bumps, which have thicknesses corresponding to height of the terminals of the device under test whose peripheral portion is warped upward relative to the central portion, are disposed, the terminals 11 of the device 10 under test and the electro-conductive members 110 may come into simultaneously contact with other to perform a test.

(a) and (b) of FIG. 11 exemplarily illustrate and describe that the signal transmission connector 100 according to one embodiment of the present disclosure is applied to the devices 10 under test, which are warped at a constant curvature, but it is also applicable to devices under test having various curvatures. That is, by measuring a warpage of the device under test and placing the electro-conductive members having the upper bumps with different thicknesses to compensate for the height deviation of the terminals of the device under test, the terminals of the device under test may compress the corresponding electro-conductive members of the signal transmission connector with a constant stroke, thereby allowing a test to be stably performed. In addition, instead of responding to the heights of the terminal one by one, it is also possible to place the electro-conductive member provided with the upper bump having a large height to correspond to only a part where the height deviation of the terminal is large.

Therefore, in the signal transmission connector according to one embodiment of the present disclosure, by placing the electro-conductive members provided with the upper bumps having different thicknesses depending on the degree of warpage of the device under test, it is possible to transmit a constant stroke to each of the electro-conductive members. Therefore, damage to the electro-conductive members due to concentrated stress applied to the electro-conductive members by the terminals of the warped device under test and contact failure due to the stroke which is not inaccurately transmitted to the electro-conductive members can be prevented, as a result, the durability of the signal transmission connector according to the embodiment of the present disclosure can be improved, and stable signal transmission can be achieved, thereby improving the efficiency of the test.

Although the present disclosure has been described with reference to preferred examples, the scope of the present disclosure is not limited to the examples described and illustrated above.

In the drawings, for example, although the signal transmission connectors in which the gap between the upper housing and the electro-conductor member is the same as that between the lower housing and the electro-conductor member are shown, it is also possible to design the gap between the upper housing and the electro-conductor member differently from the gap between the lower housing and the electro-conductor member, such as by making the gap at a part of the electro-conductive member where a lot of expansion occurs larger, taking into account the degree of expansion due to compression of the electro-conductive member.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims. The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A signal transmission connector connecting terminals of a device under test to pads of a tester, which generates a test signal, to perform an electrical test for the device under test, the signal transmission connector comprising:
a plurality of electro-conductive members, each of which being formed of an elastic insulating material in which a plurality of electro-conductive particles are arranged in a thickness direction, and having a truncated conical upper bump being able to come into contact with the terminal of the device under test, an inversed truncated conical lower bump being able to come into contact with the pad of the test, and a cylindrical connecting bump extending between the upper bump and the lower bump;
an insulating support member having an upper surface and an opposite lower surface, and provided with a plurality of support holes formed therein, each of the support holes being coupled with the corresponding connecting bump;
an upper housing formed of an inelastic material, attached to the upper surface of the support member, and having a plurality of upper housing holes, an inner wall constituting each upper housing hole being spaced apart from and surrounding the corresponding upper bump; and
a lower housing formed of an inelastic material, attached to the lower surface of the support member, and having a plurality of lower housing holes, an inner wall constituting each lower housing hole being spaced apart from and surrounding the corresponding lower bump;
wherein a width of the connecting bump is not smaller than those of a lower surface of the upper bump and an upper surface of the lower bump, and a thickness of the lower bump is not smaller than that of the lower housing.

2. The signal transmission connector of claim 1, wherein a thickness of the upper bump of at least one of a plurality of electro-conductive members differs from a thickness of the upper bump of another electro-conductive member.

3. The signal transmission connector of claim 1, wherein a thickness of the upper bump is not less than a thickness of the upper housing.

4. The signal transmission connector of claim 1, wherein a thickness of the upper bump is less than a thickness of the upper housing.

5. The signal transmission connector of claim 1, wherein the upper housing and the lower housing are formed to have the same thickness.

6. The signal transmission connector of claim 1, wherein the upper housing and the lower housing are formed to have thicknesses different from each other.

7. The signal transmission connector of claim 1, wherein each of the plurality of electro-conductive members is attached and coupled to an inner wall constituting the support hole of the support member by curing the elastic insulating material.

8. The signal transmission connector of claim 1, wherein at least one of a plurality of electro-conductive members is attached and coupled to the support hole of the support member by curing a silicone adhesive applied to a side surface of the connecting bump.

9. The signal transmission connector of claim 1, wherein the upper housing and the lower housing are made of an insulating material.

10. The signal transmission connector of claim 1, wherein the upper housing and the lower housing are made of an electro-conductive material, an insulating layer is formed on an inner wall of each of the upper housing hole and the lower housing hole.
